(19) United States
(12) Patent Application Publication
(10) Pub. No.: US 2013/0299145 A1
(43) Pub. Date: Nov. 14, 2013

(54) HEAT SINK SYSTEM

(71) Applicant: National University of Singapore, Singapore (SG)

(72) Inventors: Poh Seng LEE, Singapore (SG); Liwen JIN, Singapore (SG); Yan FAN, Singapore (SG)

(21) Appl. No.: 13/865,583

(22) Filed: Apr. 18, 2013

Related U.S. Application Data
(60) Provisional application No. 61/635,443, filed on Apr. 19, 2012.

(51) Int. Cl. F28D 15/00; B23P 15/26; H05K 7/20

(52) U.S. Cl. CPC F28D 15/00; H05K 7/20281; B23P 15/26
USPC 165/165; 29/890.03

(57) ABSTRACT

A heat sink device for use with a component for the heat transfer, the component being either a heat source or a heat sink. The device includes the features of:

A base having a curvilinear surface, which may include but not limited to a cylinder a hyperboloid, an elliptical paraboloid, a hemisphere, a sphere or a torus. The device includes an inlet for the flow of fluid through the device and an outlet to vent or drain the fluid. The device also includes a heat transfer zone located on the surface and intermediate the inlet and outlet, with the zone including a plurality of transverse channels and a plurality of oblique channels extending between adjacent transverse channels, such that the oblique and transverse channels define a fluid path for the fluid from the inlet to the outlet.

### FIELD OF THE INVENTION

The invention relates to the thermal management of components such as electrical, electronic or mechanical components whereby specific measures for the dissipation of heat are required. In particular, the invention is directed to a device to be used with such components to act as a heat sink for said heat dissipation.

### BACKGROUND

There is an urgent demand for better cooling technology to deal with the rapid rise of power and heat from various electronic components such as processors, batteries, etc. One widely used design for the cooling of small but highly heated electronics components is the use of heat sinks with micro/minichannel. They offer several advantages such as compactness, light weight and higher heat transfer surface area to fluid volume ratio which makes it more attractive compared with other macro-scale systems

Micro/mini channel geometries can be designed to generate secondary flow that enhances heat transfer. This technique can be applied by incorporating offset strip fins, chevron plates and other similar geometries.

### SUMMARY OF INVENTION

In a first aspect, the invention provides a heat sink device for use with a component for the heat transfer, the device comprising: a base having a curvilinear surface; an inlet for receiving a fluid; an outlet for venting said fluid; a heat transfer zone located on said surface and intermediate the inlet and outlet; said zone including a plurality of transverse channels and a plurality of oblique channels extending between adjacent transverse channels; wherein said oblique and transverse channels define a fluid path for a fluid from the inlet to the outlet.

In a second aspect, the invention provides a heat sink device for use with a component for the heat transfer, the device comprising: a base having a cylindrical surface; an inlet for receiving a fluid; an outlet for venting said fluid; a heat transfer zone located on said surface and intermediate the inlet and outlet; said zone including a plurality of transverse channels and a plurality of oblique channels extending between adjacent transverse channels; wherein said oblique and transverse channels define a fluid path for said fluid from the inlet to the outlet.

In a third aspect, the invention provides a process for forming a heat sink device for use with a component for the heat transfer, the process comprising the steps of: forming a base; forming a heat transfer zone on said surface; said zone including a plurality of transverse channels and a plurality of oblique channels extending between adjacent transverse channels; wherein said oblique and transverse channels define a fluid path for said fluid from the inlet to the outlet.

The invention provides an oblique fin channel heat transfer to mount to the non-planar surface of a heat source possibly in the form of an enveloping jacket. The periodic oblique fin causes the hydrodynamic boundary layer development to be reinitialized at the leading edge of the next downstream fin. This decreases the average thermal boundary layer thickness, enhances the heat transfer performance and may yield a negligible pressure drop penalty due to combined effect of thermal boundary layer re-development and flow mixing.

In one embodiment, the heat transfer device may be “wrapped” about the component, eliminating edge effects leading to heat concentrations. Such edge effects may manifest due to the flow migration via the oblique channels, such as if there is either no new supply of fluid or too much fluid supplied to the boundaries of the fin array that are parallel to the main flow, thus resulting in temperature non-uniformity in the span-wise direction. The ability to wrap about a component may act as a remedial device where such end effects have been created by conventional heat transfer system, by enclosing or enveloping an area suffering such a heat concentration. In such cases, the use of “open shapes” for the curvi-linear surface may be particularly useful. Such open shapes may act as “patches” to cover the edge effects, or extensions of a broader heat transfer device.

The base may be a separate mountable surface to be mounted to the component. Alternatively, the base may be a wall of the component and so the device may form part of the component.

The base may be a rigid element, such as a molded plastic or metal piece shaped to fit the required component. Alternatively, the base may be a deformable element, capable of being deformed to fit to the required shape. In this case, a metal (such as copper or aluminium) or plastic (reinforced or non-reinforced) sheet may be applicable.

The heat transfer device may be applicable for heat dissipation of components to which the device is mounted. Such applications may include the heat dissipation from electronic components

By way of example, the heat transfer device according to various embodiments of the present invention may be used with inductor and transformer coils, motors and generators and gearboxes, where high voltage and current through its winding results in extremely high temperature in its core. For high capacity batteries such as for electric/hybrid vehicle batteries capacity and longevity may decrease even explode. Further, high power LEDs or high power lasers experience losses of up to 70% of total energy consumption emitted as heat. Other components such as engines, gearboxes, drills and even nuclear fuel rods can also produce excessive heat that needs to be dissipated to ensure performance, reliability and safety.

In an alternative application, the invention may be used to impart heat, and so act in a reverse heat transfer direction. Such applications may include mounting a heat transfer device according to the present invention to a thermal mass, such as a thermal mass used to heat a building. A heated fluid may be forced through the heat transfer device, transferring heat to the device which in turn heats the thermal mass. The source of heat for the fluid may be geothermal, solar thermal or waste energy from a power plant or other industrially generated heat. In the latter application, the heat transfer device may act as a means to facilitate energy recovery for green building technology applications.

The heat transfer device may be a closed shape, such as a cylinder, elliptical prism, hyperboloid or cone (parabolic or otherwise. Alternatively, it may be an open shape such as an elliptic paraboloid, hyperbolic paraboloid, hemisphere etc.

In the case of the cylindrical heat transfer device, the oblique channels may be wider than the transverse channels projecting parallel to the axis of the cylinder. In this case, the varying ratio of channel widths may induce helical flow about the heat transfer device. The extend flow path for the primary fluid flow may yield a higher transfer of heat between the fins and the fluid.

The channels within the heat transfer device may be defined by heat transfer fins shaped to form the transverse and oblique channels. The fins may include edges at the interface between the transverse and oblique channels, with transverse channel faces and oblique channel faces. Upstream edges may be rounded so as to reduce the “shock losses” associate with the change in direction of the flow from the transverse to oblique channel. Further, or alternatively, downstream edges may be rounded to as to similarly reduce shock losses associated with the change of direction from the oblique channel to the transverse channel.

These rounded edges, through the reduction in hydraulic losses, may overall reduce the pressure loss for the fluid passing through the heat transfer device. This may lead to an overall reduction in pressure required, and so a reduction in the size of the pump required. Alternatively, for a more complex curvilinear surface shape, the rounded edges may balance the increased losses associated with the more complex surface.

Its cooling effectiveness is compared with conventional straight fin minichannel heat sinks through experimental and numerical approach for the Reynolds number ranged from 50 to 500. The results showed that the averaged Nusselt number, Nuₐᵥₑ for the cylindrical oblique-cut fin minichannel heat sink increases up to 75.6% and the total thermal resistance decreases up to 59.1% when compared with the conventional straight fin minichannel heat sink. It is also found firstly that a flow recirculation zone will form at larger Reynolds number in the secondary channel however this recirculation is insignificant in the present low Reynolds number study. Heat transfer enhancement (E_{Nu}) and pressure drop penalty (E_{f}) show that a significant improvement of the cylindrical oblique fin minichannel over conventional straight fin minichannel overall.

### BRIEF DESCRIPTION OF DRAWINGS

The patent or application file contains at least one drawing executed in color. Copies of this patent or patent application publication with color drawing(s) will be provided by the U.S. Patent and Trademark Office upon request and payment of the necessary fee.

It will be convenient to further describe the present invention with respect to the accompanying drawings that illustrate possible arrangements of the invention. Other arrangements of the invention are possible and consequently, the particularity of the accompanying drawings is not to be understood as superseding the generality of the preceding description of the invention.

FIG. 1A is an isometric view of a cylindrical heat transfer device according to one embodiment of the present invention;

FIG. 1B is a detailed view of the transverse channels and oblique channels of the heat transfer device of FIG. 1A;

FIGS. 2A to 2G are isometric views of heat transfer devices having curvilinear surfaces according to a further embodiment of the present invention;

FIG. 3 is a schematic view of an experimental arrangement for testing a heat transfer device.

FIG. 4 is a cross-sectional view of a heat transfer device according to a further embodiment of the present invention.

FIGS. 5A and 5B are temperature characteristics comparing the performance of the prior art to the present invention;

FIGS. 6A and 6B are velocity and temperature contours for a heat transfer device according to a further embodiment of the present invention;

FIGS. 7a to 7d are flow contours for varying Reynold's numbers of a heat transfer device according to a further embodiment of the present invention;

FIGS. 8A to 8C are characteristics for a heat transfer device according to a further embodiment of the present invention;

FIGS. 9A to 9B show experimental data for comparing performance of the prior art and one embodiment of the present invention;

FIG. 10 is an isometric view of a heat transfer device according to a further embodiment of the present invention, and;

FIG. 11 is a performance characteristic comparing embodiments of the present invention.

### DETAILED DESCRIPTION

A characteristic of the present invention is the ability to maintain efficient heat transfer to components having varying shapes, in particular, those components having an external curvilinear surface.

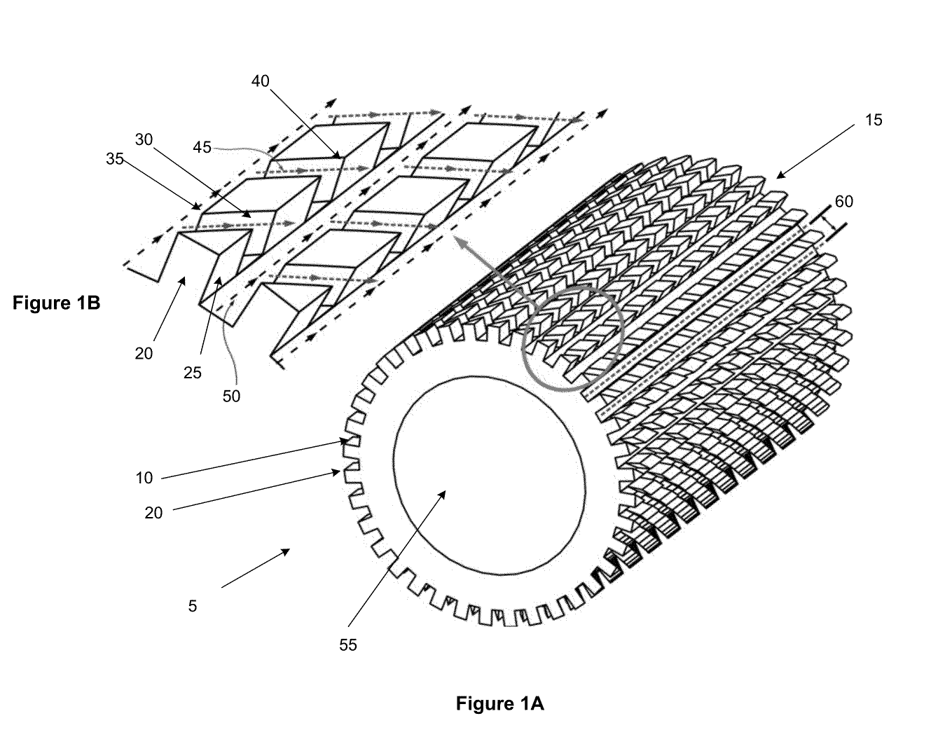

FIGS. 1A and 1B show one such example whereby a heat transfer device 5 has a cylindrical surface so as to encompass a cylindrical shaped component in an orifice 55. Such a component may include a cylindrical battery, a combustion chamber or sleeve containing a reciprocally moving object.

The heat transfer device includes an inlet end 10 and an outlet end 15, though for clarity both the inlet and outlet for the fluid passing through the heat transfer device are omitted for clarity, and so showing only the heat transfer zone.

The heat transfer zone comprises an array of heat transfer fins 20, providing boundaries for the transverse channels 50 with oblique channels 45 passing between the fins 20. Each fin includes a pair of transverse faces 25 defining the transverse channels and oblique faces 30 defining the oblique channels. Further, in this embodiment, the fins have a quadrilateral shape, having an upstream edge 35 and a downstream edge 40. The fins are spaced 60 to provide sufficient density to the transverse channels based upon the required fluid flow for the heat transfer application. The width of the transverse channels is greater than that of the oblique channels. In one embodiment, specific to the cylindrical surface application, the transverse channels may be narrower than the oblique channels, imposing a helical flow for the fluid.

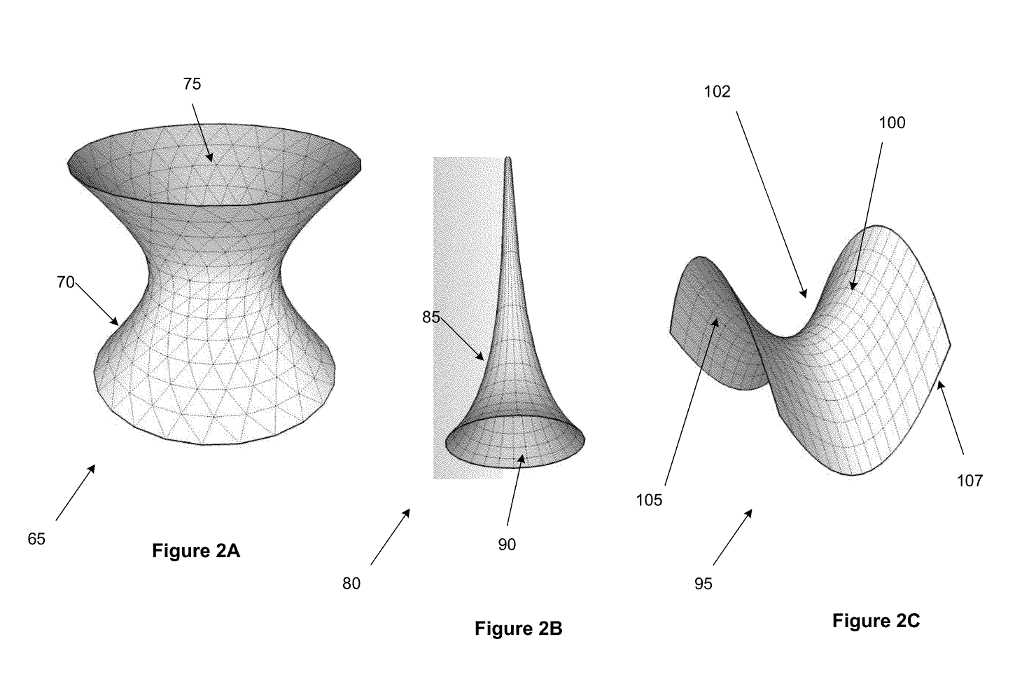

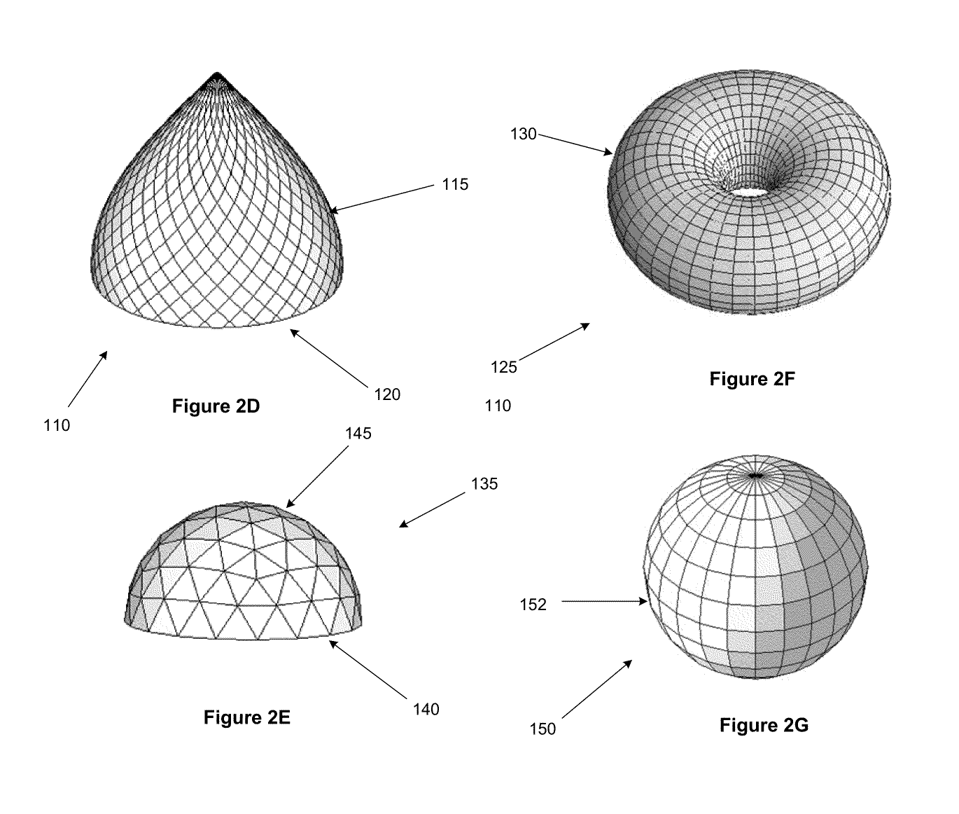

With reference to FIGS. 2A to 2G, other applications of the heat transfer device are shown. FIGS. 2A, 2B and 2D to 2G show closed shapes. An open shape 120 is also shown in FIG. 2C.

Specifically, having a heat transfer device as shown in FIG. 2A, using a hyperboloid 65 or similar shape may be applicable for the cooling of flow restriction for a small scale pressure meter, whereby a flow of heated fluid through an orifice 75 may require cooling due to the losses imposed by the restriction.

FIG. 2B shows a parabolic cone 80 which may similarly be used for a flow restriction in a venturi device where flow is restricted through the bore 90.

The elliptical paraboloid 95 of FIG. 2C may be used as a cover for a cylinder head assembly, so as to cool the areas 100, 105 above the combustion chambers, as well as the central point 102 between the fuel injectors.

The heat transfer devices of FIG. 2D and 2E show different embodiments 110, 135 to cool the tip of a vehicle in the aerospace industry particularly for high speed vehicles prone to skin friction limitations such as scram jets, re-entry vehicle or orbital delivery systems.

The torus 125 of FIG. 2F may be useful for cooling a magnetic coil such as for an MRI machine. The sphere 150 of FIG. 2G may be applicable for pressure vessel, or for the thermal isolation of a foundry material during road transport.

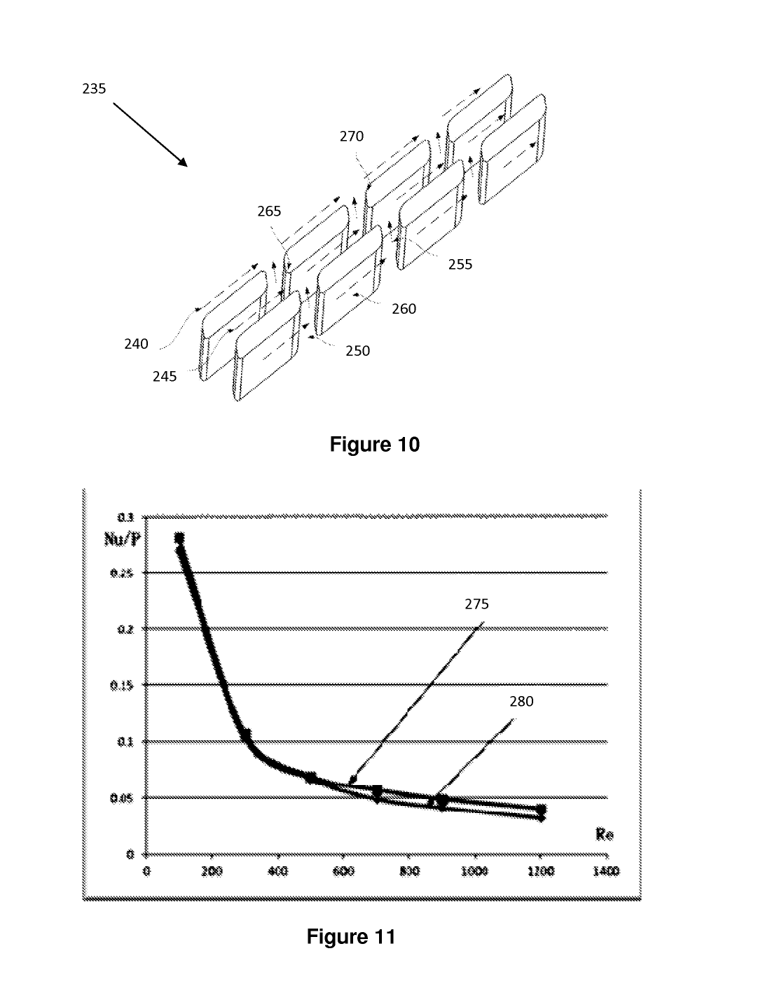

An alternative arrangement of the heat transfer fins is shown in FIG. 10. Here, the primary flow 240 passes down the transverse channels 245, developing a secondary flow 255 in the oblique channels 250. In this embodiment, the heat transfer fins 260 within the heat transfer zone 235 have been modified by rounding the upstream edge 265 and downstream edge 270. The rounding of these edges contributes to a reduction in pressure losses as the secondary flow 255 develops. This has an overall reduction in pressure loss for the entire heat transfer device, as the required pumping power is reduced significantly without compromising the heat transfer performance

It will be appreciated that, for manufacturing ease or other consideration, one or both of the upstream and downstream edges may be rounded, providing a partial of full reduction in pressure loss.

FIG. 11 shows the ratio of Nusselt number to pressure drop. By rounding the upstream and downstream edges 265, 270, the higher ratio of Nusselt number to pressure drop of rounded heat transfer fins 260, the lower power is required for reaching the performance when compared to conventional fins.

An optimized heat transfer fin structure for different application requirements may be achieved by varying the dimension of oblique channels 250 on the fins 260.

Fabrication cost may be reduced by machining fins on the planar surface and then wrapping to any enclosing oblique-finned structure. There are various micro fabrication including forging processes, which may also depend on the material, such as copper, aluminum, plastic, etc.

### Numerical Studies

A numerical 3D conjugate heat transfer simulation is carried out based on the specific test pieces used in the experiments, with considerations on both heat convection in the channel and conduction in the copper substrate. The minichannel with oblique fins exhibited a periodic pattern along the circumference as seen from the 3D views in FIGS. 1A and 1B. Hence, in order to reduce the computation domain, the periodic geometry for the analysis consist of a full width fin at the centre and half width channels on each side was used. For the periodic boundary condition, the flow is considered as opposing periodic plane and is a direct adjacent to the first periodic boundary. Hence, when calculating the flow through the periodic boundary adjacent to a fluid cell, the flow conditions at the fluid cell adjacent to the opposite periodic plane were used. In FIG. 1B, it shows enlarged view of the simplified periodic computational domain for this model. In this simulation, the geometrical parameters details for both conventional straight fin minichannel and cylindrical oblique fin minichannel can be found in FIG. 1B. With regard to the material selection, water-liquid is selected for working fluid while copper with thermal conductivity, k_{cu}=387.6 W/m·K is assigned as the fins and heat sink substrate material. The continuity equation and the Navier-Stokes equations in their steady, incompressible form, along with the associated boundary conditions were solved. Therefore, the governing equations for the fluid flow are the following form of the incompressible equations, respectively, continuity equation, momentum equation, and energy equations for liquid and solid listed as followings:

∇·(ρ\vec{v})=0 (1)

∇·(ρ\vec{v}\vec{v})=−∇P+∇·(μ∇\vec{v}) (2)

∇·(ρ\vec{v}CₚT)=∇·(k∇T) (3)

∇·(k∇T)=0 (4)

For the cylindrical oblique cut fin minichannel, the hydraulic diameter can be defined as followings (5) when the microchannel flow cross section is not constant:

$${D}_{h} = \frac{4 {A}_{eq} L}{A} \qquad ( 5 )$$

Thus, the Reynolds number in both simulation and experiment is defined by

$$Re = \frac{ρ {vD}_{h}}{μ} \qquad ( 6 )$$

where ρ is the fluid density, v is the average fluid velocity at A_{eq} and μ represents the fluid viscosity. The friction factor is defined as

$$f = \frac{Δ P}{\frac{1}{2} ρ {v}^{2} \frac{L}{{D}_{h}}} \qquad ( 7 )$$

In the numerical simulation, local wall temperature T_{w}(x)and local fluid bulk mean temperature T_{f}(x) can be obtained by:

$$\begin{matrix}{T}_{w} ( x ) = \frac{{\sum }_{Y , Z} {T}_{w} ( X , Y , Z ) dA ( X , Y , Z )}{{\sum }_{Y , Z} dA ( X , Y , Z )} & ( 8 ) \\ {T}_{f} ( x ) = {T}_{i n} + \frac{{\sum }_{X , Y , Z} {q}^{″} ( X , Y , Z ) dA ( X , Y , Z )}{{mC}_{p}} & ( 9 )\end{matrix}$$

where A(x) and q(x) are the total local heat transfer area and total local heat input separately, which is defined as follows:

$$\begin{matrix}A ( x ) = {\sum }_{Y , Z} dA ( X , Y , Z ) & ( 10 ) \\ q ( x ) = {\sum }_{Y , Z} {q}^{″} ( X , Y , Z ) dA ( X , Y , Z ) & ( 11 )\end{matrix}$$

The local heat flux h(x) and local Nusselt number Nu(x) can be obtained from:

$$\begin{matrix}h ( x ) = \frac{q ( x )}{A ( x ) [ {T}_{w} ( x ) - {T}_{f} ( x ) ]} & ( 12 ) \\ Nu ( x ) = \frac{h ( x ) {D}_{h}}{{k}_{f}} & ( 13 )\end{matrix}$$

where k_{f} is the thermal conductivity of water. The average Nusselt number for minichannel, Nuₐᵥₑ can then be calculated based on the axially weighted average values of Nu(x) by:

$${Nu}_{ave} = \frac{\sum Nu ( x ) dx}{X} \qquad ( 14 )$$

In order to conduct an accurate computational simulation, grid independence study is carried out to obtain a sufficiently finer mesh file. The entire computational domain was meshed with hexahedral elements with the Map scheme and a total of 682,500 (650×30×35) cells were generated. Simulations with different grid showed satisfactory grid independence for the results obtained with this mesh. The resultant average Nusselt numbers from different meshes used were in close proximity to each other. For instance, average Nusselt numbers of 6.294, 6.398 and 6.399 were obtained with the mesh counts of 650×30×35 cells, 650×15×35 cells and 325×15×35 cells, respectively for the case of conventional minichannel. The average Nusselt number was varied by 1.6% from the first to the second mesh, and only by 0.015% from the second to the roughest grid. Thus, the intermediate grid (650×15×35 cells) was selected. On the other hand, average Nusselt numbers of 14.849, 14.884 and 14.892 were achieved with the mesh count of 650×30×35 cells, 650×15×35 cells and 325×15×35 cells, respectively for the case of cylindrical oblique fin minichannel. The variations in average Nusselt numbers were 0.235% from the first to the second mesh, and 0.054% from the second to the roughest grid. Likewise, the intermediate grid (325×15×35 cells) was selected for cylindrical oblique fin minichannel.

Since the Navier-Stokes equations were solved inside the domain, no-slip boundary conditions were applied on the channel walls for all cases. The inlet temperature of the coolant (liquid-water in this case) was set as room temperature 297 K (24° C.). A uniform flow profile was applied at the inlet and pressure outlet condition was prescribed at the outlet. In the 3D conjugate simulation, the substrate material is copper and the thickness in the model is the distance in experimental test piece from channel bottom wall to thermocouple location which is in order to match the real condition. Since copper has relatively high thermal conductivity, heat flux in the substrate can be well approximated to uniform. 1 W/cm² heat flux was supplied evenly from the bottom of the substrate while the top surface of the copper microchannel was assumed bonded with an adiabatic material and compared with experimental measurements. A residual of 1×10⁻⁶ is set as the convergence criteria for the continuity equation, X velocity, Y velocity and Z velocity while that for the energy equation is set as 1×10⁻⁹.

### Experimental Setup and Procedures

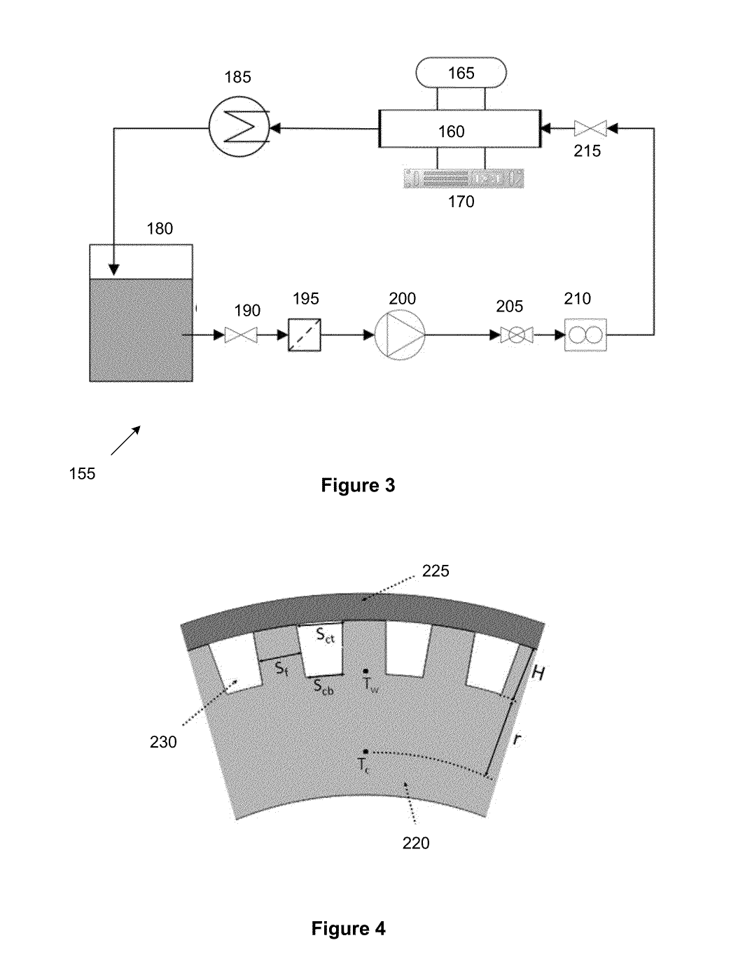

FIG. 3 shows the general schematic for the experimental setup. The setup consists of a reservoir, liquid-to-air heat exchanger, valves, filter, gear pump, flow meter, data acquisition system, DC power supply, computer, pressure transducer , thermocouples and test section where the section holds the test piece assembly. A rectangular container of size 12 cm×15 cm×20 cm made of polycarbonate material is used for the storage of the de-ionized water. During the test, de-ionized water is pumped into the test section through the flow loop using a gear pump and the flow rate is measured using a turbine liquid flow meter with a measurement range of 100-1000 ml/min. Temperature measurements are obtained at the inlet and outlet plenum of the test section as well as another eight locations below the channel surface of the test piece using thermocouples. The pressure drop between the inlet and outlet plenum of the test section is measured using ultra low differential pressure transmitter. The test section is heated using a cartridge heater which is powered by a 850 W Programmable DC power supply with an output range of 0 to 150 V and 0 to 5.6 A. In order to maintain a constant temperature of the water in the reservoir after it is pumped out from the test section, a liquid-to-air heat exchanger is used to regulate the desired temperature before the water is pumped back into the reservoir.

The test section consists of four parts namely the housing, the cover, the top adaptor and the copper block microchannel heat sink. The housing comprises of the top housing, the bottom housing and the main housing, all of which are made of Teflon. The top housing holds the top adaptor, top cover and microchannel heat sink. It has two O ring slots, one within the top plate and the other at the top housing to prevent leakage. At the top and bottom housing, there are independent pressure and temperature ports for measuring the fluid properties before and after bypassing the heat sink. The microchannel heat sink is made from a copper block which microchannels are cut on the surface using CNC machining process. There are eight holes adjacent to each other around the circumference below the channel surface in the block for inserting the thermocouples to measure the heat sink's stream wise temperature distribution. These eight holes were drilled 4.5 mm below the channel surface, 13 mm, 26 mm, 39 mm and 52 mm below the outlet plenum respectively. The bottom housing was used to hold the bottom cover and microchannel heat sink and provided uniform flow to the inlet channels.

Experiments were carried out on minichannel heat sinks with conventional straight parallel channels and novel cylindrical oblique fin channels. The detailed dimensions for both are given in Table 1 below.

TABLE 1
Minichannel geometry details.

| | Conventional | |
|---|---|---|
| | straight fin | |
| Characteristic | minichannel | Oblique fin minichannel |
| Material | copper | |
| Footprint dimension D, (mm) | 18 | |
| Fin length L (mm) | 65 | |
| Number of rows | 36 | |
| Channel height H, (μm) | 2001.9 | 2038.5 |
| Main channel bottom width (μm) | 1365.4 | 1531.9 |
| Main channel top width (μm) | 1729.8 | 1973.4 |
| Fin width (μm) | 1598.0 | 1542.3 |
| Aspect ratio, α | 1.47 | 1.31 |
| Number of fins per row | — | 11 |
| Secondary channel length (μm) | — | 2008.4 |
| Oblique fin length (μm) | — | 3743.9 |
| Oblique angle θ (°) | — | 30.8 |

The steady-state heat gain by the water can be determined from the energy balance equation below:

q=ρCₚQ(T_{f,o}−T_{f,i}) (15)

The volumetric flow rate Q is measured with a flow meter. The inlet and outlet fluid mean temperature (T_{f,o} and T_{f,i}) are obtained using the two thermocouples positioned immediately upstream and downstream of the microchannel respectively. The density and specific heat are calculated based on the mean fluid temperature T_{f,ave} (average of the fluid inlet and outlet temperatures). The amount of heat loss that is dissipated via other means such as natural convection, radiation, and conduction through the housing are experimentally determined by the following equation:

$${q}_{heatloss} \% = \frac{{q}_{input} - {q}_{heatgain}}{{q}_{input }} \times 100 \% = \frac{UI - q}{UI} \times 100 \% \qquad ( 16 )$$

The qᵢₙₚᵤₜ input power is supplied via the 850 W Programmable DC power supply. It is found that more than 85% of the heat input power is transferred to the fluid when the Reynolds number is more than 50 and the unintended heat loss is below 15%. Therefore, the effective average heat flux based on the base area is calculated using the measured sensible heat gain using Eq. (16). The local heat transfer coefficient and the average heat transfer coefficient can be determined using the equations:

$$\begin{matrix}{h}_{x} = \frac{q}{{A}_{tot} ( {T}_{w , i} - {T}_{f , x} )} & ( 17 ) \\ {h}_{ave} = \frac{q}{{A}_{tot} ( {T}_{w , ave} - {T}_{f , ave} )} & ( 18 )\end{matrix}$$

T_{w,i} is the local wall temperature. Constant surface heat flux condition was assumed in the experiment due to the high thermal conductivity of copper. Thus the fluid bulk mean temperature at location x, T_{f,x}, was calculated using the following equation:

$${T}_{f , x} = {T}_{f , i} + \frac{{T}_{f , o} - {T}_{f , i}}{L} \times x \qquad ( 19 )$$

T_{w,ave} is the average local microchannel wall temperature and T_{f,ave} is the average fluid temperature. Aₜₒₜ is the total area of convective heat transfer surface. The followings equation are then referred

Aₜₒₜ=NA_{ch}=A_{b}+ηA_{fin} (20)

where A_{b} is the unfinned surface area at the bottom of the channels and A_{fin} is fin area. A_{ch} is the area available for convection per channel, L(w+2ηH). Fin efficiency η is used to account for the temperature drop through the extended fins. The non-conductive material (Teflon) is assumed to be an adiabatic fin tip condition. The Fin efficiency η is correlated by

$$η = \frac{tanh ( m H )}{m H} where m = \sqrt{\frac{h {p}_{f}}{{k}_{cu} {A}_{c}}} \qquad ( 21 )$$

Since direct measurement of the microchannel wall temperature is not available, it is determined by extrapolation from the temperature measured in the copper block by assuming 1-D heat conduction as showing in FIG. 4,

$${T}_{w , i} = {T}_{cu} - \frac{q ln ( 17 / 12.5 )}{2 π {Lk}_{cu}} \qquad ( 22 )$$

Average wall temperature is then obtained as

$${T}_{w , ave} = \frac{{\sum }_{i = 1}^{8} {T}_{w , i}}{8} \qquad ( 23 )$$

p_{f} is the fin perimeter and A_{c} is the fin cross section area. The corresponding local Nusselt number and average Nusselt number is calculated as

$$\begin{matrix}{Nu}_{x} = \frac{{h}_{x} {D}_{h}}{{k}_{f}} & ( 24 ) \\ {Nu}_{ave} = \frac{{h}_{ave} {D}_{h}}{{k}_{f}} & ( 25 )\end{matrix}$$

where Dₕ is the hydraulic diameter of the channel and k_{f} is the thermal conductivity of water.

Total thermal resistance of the heat sink is defined as

$${R}_{tot} = \frac{{T}_{ave} - {T}_{i n}}{q} \qquad ( 26 )$$

where Tₐᵥₑ is the average wall temperature of the heat sink, Tᵢₙ is the inlet coolant temperature and q is the heat gain by the water.

As for material properties, copper is assumed to have a constant thermal conductivity of k_{cu}=387.6 W/m·K. The density, specific heat capacity, thermal conductivity and dynamic viscosity of water are evaluated at the mean fluid temperature (average of the fluid inlet and outlet temperatures). As the pressure taps are located upstream and downstream of the minichannel in the inlet and outlet plenum, the measured pressure drop includes the sum of pressure drops from inlet plenum to the outlet plenum and the minor losses due to abrupt contraction and expansion at the inlet and outlet. The pressure drops reported here are obtained as followed:

Δ=ΔP_{c}+ΔP_{ch}+ΔPₑ (27)

The pressure drop across microchannel can be calculated as

ΔP_{ch}=ΔP−ΔP_{c}−ΔPₑ (28)

where ΔP_{c} and ΔPₑ are the contraction pressure losses from the shallow plenum to the microchannel inlet and expansion pressure losses from the microchannel outlet to the shallow plenum. These minor losses can be expressed as the followings:

$$\begin{matrix}Δ {P}_{c} = \frac{1}{2} {ρ}_{f} ( {v}_{i n}^{2} - {v}_{s , i n}^{2} ) + \frac{{K}_{c}}{2} {ρ}_{f} {v}_{i n}^{2} & ( 29 ) \\ Δ {P}_{e} = \frac{1}{2} {ρ}_{f} ( {v}_{s , o}^{2} - {v}_{o}^{2} ) + \frac{{K}_{e}}{2} {ρ}_{f} {v}_{o}^{2} & ( 30 )\end{matrix}$$

where s denote the shallow plenum, K_{c} and Kₑ are the loss coefficients due to the abrupt contraction and abrupt expansion. K_{c} (1.1 and 0.3) and Kₑ (0.15 and −0.25) are chosen for conventional straight fin and cylindrical oblique fin separately.

T type thermocouples with an absolute uncertainty of ±0.520 C. are used. The maximum allowable error for the flow meter is ±0.5% full scale. As for the differential pressure transmitter for measuring the pressure drop between inlet and outlet, the tolerance is ±1% full scale. The absolute uncertainty in dimension measurement is ±5 μm. A standard error analysis is used to calculate the uncertainties of various variables. In the steady-state, the uncertainty of sensible heat gain by the water is 20%, and the revealed uncertainties heat transfer coefficients to be 21.9%. Suppose that x, . . . , z are measured with uncertainties δx, . . . , δz, and the measured values used to compute the function q(x, . . . , z). If the uncertainties in x, . . . , z are independent and random, then the uncertainty in q is

$$δ q = \sqrt{{( \frac{\partial q}{\partial x} δ x )}^{2} ++ … + {( \frac{\partial q}{\partial z} δ z )}^{2}} \qquad ( 31 )$$

After the test section is assembled, the gear pump is switch on and the desired flow rate within the flow loop is set using the gear pump and ball valve. When the flow rate and inlet fluid temperature are stabilized, the power supply to the heaters is set to the desired value. Steady state is reached after about 30-50 min in each test run when all temperature readings are within ±0.1° C. for about 2 min. Steady state readings from the thermocouple, differential pressure transmitters and flow rate are recorded and stored throughout the experiment. All power, temperature, pressure and flow rate measurements are averaged over a 2 min period. The flow rate is then increased for the next test, and the experimental procedure repeated. Experiments were conducted at flow rate ranged from 50 ml/min to 900 ml/min and heat input is from 50 W to 300 W.

### Results

The experimental investigation on both conventional and cylindrical oblique fin minichannel heat sinks is conducted over the flow rates ranged from 50 ml/min to 900 ml/min, which correspond to Reynolds numbers of 50 to 500 and with the heat input ranged from 50 W to 300 W. Since

$$\frac{L}{Re {D}_{h}} 〉 0.05 ( hydro \text{-} dynamically fully developed ) and$$

$$\frac{L}{Re {D}_{h} {P}_{r}} 〈 0.05 ( thermally developing ) ,$$

all the experimental data correspond to the thermally developing regime criterion.

### Validation of Numerical Simulation

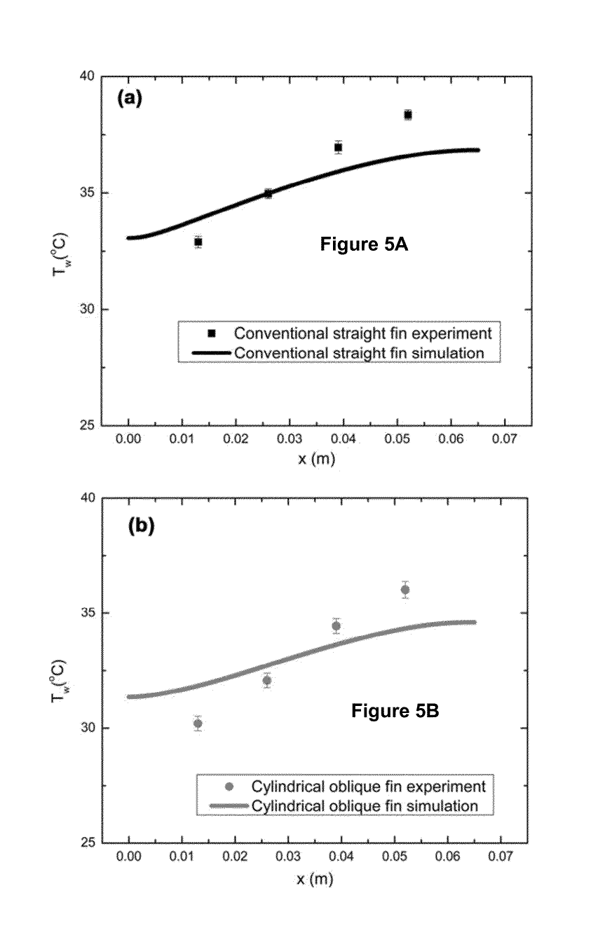

FIGS. 5A and 5B show the wall temperature distribution on the heat sink surface at different stream wise locations when the flow rate is at 400 ml/min The continuous lines are obtained from simulation while the dots are obtained from experiments. It is found that the deviation between experimental and numerical results is less than 6% under all conditions. This means the numerical simulation studies are validated by the experiments. It is also observed that the wall temperature in the heat sink is increased along the stream wise location. This indicates that the thermal boundary layer thickens when the fluid travels in the downstream.

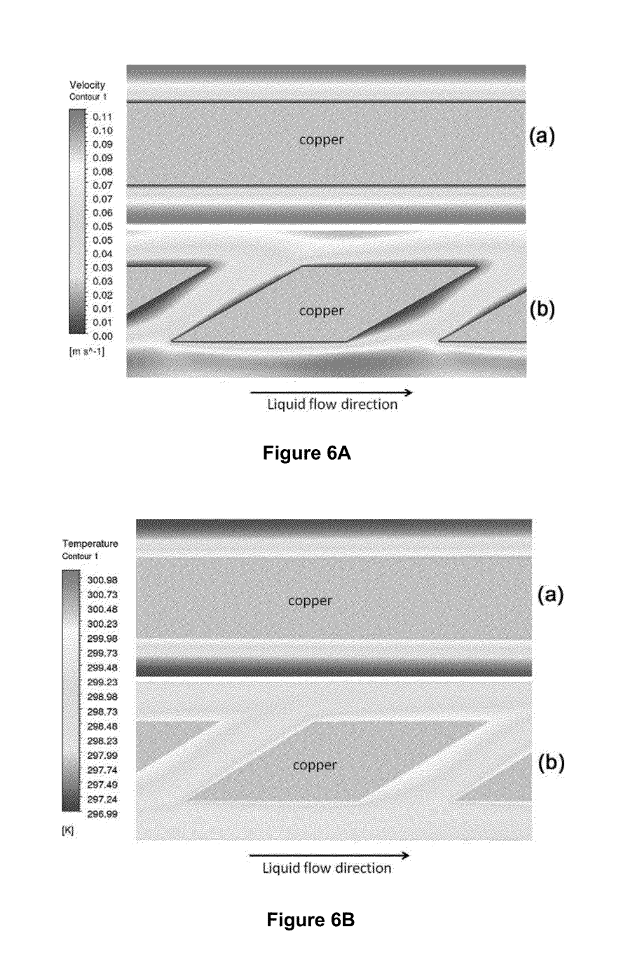

Simulation results reveal a clear flow field difference between the conventional straight fin minichannel and oblique fin minichannel. FIG. 6A show the velocity profile at mid-depth (z=18 mm), mid-portion of the minichannel (x=30-35 mm) when the flow rate is 400 ml/min. From FIG. 6A(a), it can be seen that the high velocity gradient from minichannel wall to the fluid core implies the hydraulic boundary layer is fully developed and maintained throughout the whole conventional straight fin minichannel. Nevertheless, in FIG. 6A(b), it is observed that the sectional oblique fin disrupts the velocity profile at each entrance of the next downstream fin and causes the hydrodynamic boundary layer development to reinitialize at every downstream oblique fin. This results in the boundary layer thickness reducing significantly in comparison with the conventional straight fin minichannel. Thus the velocity profile is maintained in the developing region throughout the whole channel.

Convective heat transfer takes place through both diffusion and advection. Heat is transported from copper surface into the fluid particle and propagates further into the fluid core. Due to the significant flow field difference, a large fluid temperature distinction is found between the conventional straight fin minichannel and oblique fin minichannel in the temperature contour in FIG. 6B(a), it can be seen that the fluid temperature difference is 4K which is from 296.99K to 300.98K in the conventional straight fin minichannel. It is observed that the temperature gradient between the near wall fluid and core fluid is highly developed and the thermal boundary layer keeps increasing as the fluid travels downstream in the conventional straight fin minichannel. This phenomenon could deteriorate the convective heat transfer and reduces the cooling effect on the copper surface. However, in FIG. 6B(b), the temperature contour inside the oblique fin minichannel exhibits a more uniform fluid temperature distribution from 298K to 300K. It is found that a portion of main flow is diverted into the secondary channel due to the presence of the oblique cuts on the solid fins. This secondary flow, which carries momentum driven by pressure difference, injects into the adjacent main channel which disrupts the boundary layer and accelerates the heat transfer into the core fluid. This results in the better fluid mixing and superior heat transfer performance which leads to lower surface temperature.

### Secondary Channel Flow Distribution

An important phenomenon that affects the heat transfer significantly is how the fluid mixes inside the minichannel. This is a complex physical process which follows the convective diffusion equation which in turn contains fluid motion terms that are governed by the Navier-Stokes equations. It is useful to bring the flow field mechanism to account for the heat transfer performance in the cylindrical oblique fin heat sink. Due to experimental limitations, the present study focuses on fluid mixing to study the effects of the secondary flow on the minichannel based on the numerical simulation results. This is feasible since the 3D conjugate simulation predictions generally agree with the experimental results. Since the oblique fin configuration is periodic, simulation studies focus on flow within a single channel domain instead of the full domain.

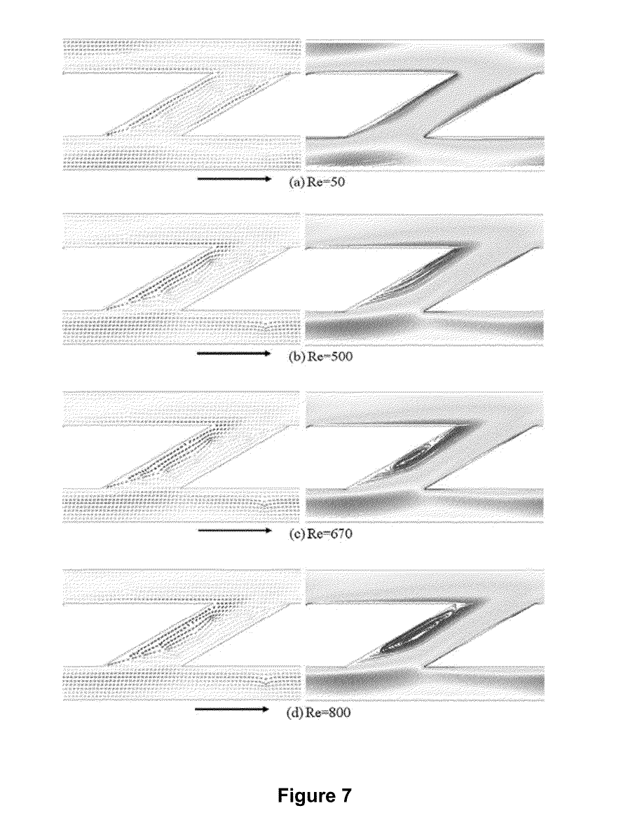

FIG. 7 shows the typical cross stream (X, Z) velocity vector and streamline at the middle location in the downstream (X) direction. As fluid is forced into the oblique fin cylinder, coolant travels along the main channel as well as into the secondary channel of the cylinder. When the Reynolds number is as low as 50, the streamlines in the secondary channel is uniform and orderly. The velocity is much lower in the secondary channel comparing with that in main channel. This implies that oblique fin has less effect for flow mixing in the low Reynolds number region.

When the Reynolds number increases to 500, the streamlines near the trailing edge becomes rarefaction but the velocity is still in a relatively order pattern. This is due to secondary flow carrying higher energy and momentum that improves the flow mixing. The flow distribution is non uniform since there is a slight adverse pressure gradient near the trailing region of the oblique fin. The main channel boundary layer keeps re-developing at each oblique angle and this enhances the heat transfer performance.

When the Reynolds number increases to 670, the adverse pressure gradient at the trailing edge of the secondary channel enlarges and a recirculation zone whirling in a clockwise direction is formed. This recirculation results in a very high shear stress near the trailing edge of the secondary flow and this incurs additional pressure drop since the flow in the recirculation region has high energy that cannot be dissipated.

When the Reynolds number is 840, the flow recirculation is further intensified, which is shown as a larger recirculation zone area in FIG. 7(d). The presence of this region with higher velocity gradients causes an increase in turbulence and shear stress. The net mass flow region through the secondary channel reduces substantially and this may produce unfavorable effect in flow mixing. As a result, it hinders the heat transfer and suffers a high pressure drop penalty.

The flow region may manifest as FIGS. 7(a) and (b). The recirculation is insignificant and the motion of the particles in the secondary channel fluid is orderly with all particles moving in straight lines parallel to the boundary wall. In the main channel, boundary layer is broken and thinned at each entrance of the secondary channel. This particular phenomenon decreases the average thermal boundary layer thickness and enhances the heat transfer performance while undergoing comparable pressure drop penalty due to combined effect of thermal boundary layer re-development and flow mixing.

### Heat Transfer Characteristic

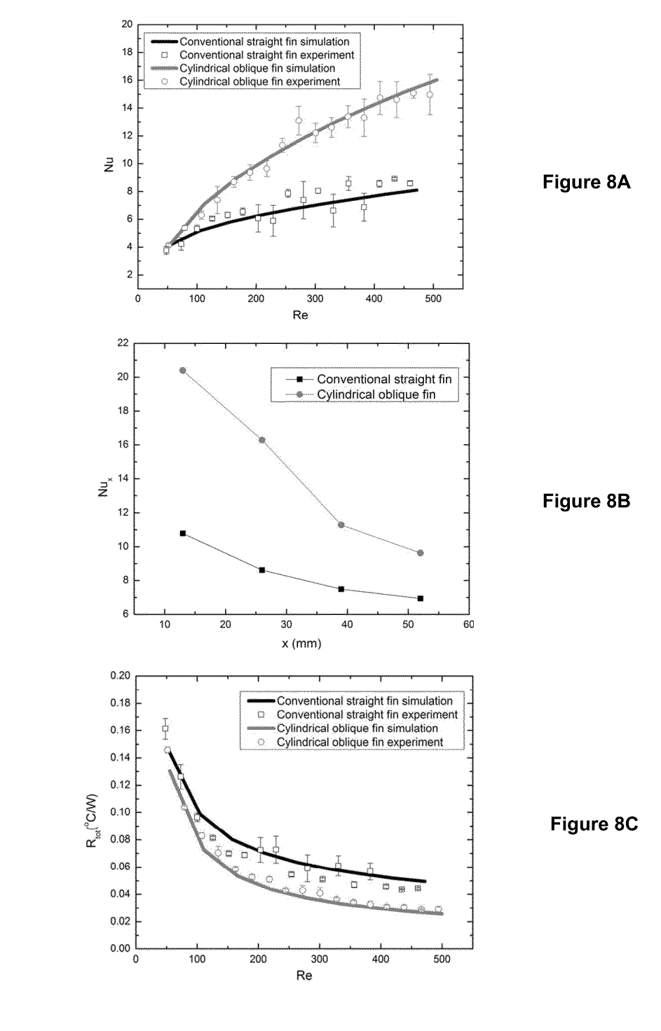

FIG. 8A shows the graph of the average experimental and numerical Nusselt number against Reynolds Number for both conventional and cylindrical oblique fin minichannel heat sinks. The experimental values of the Nusselt number are derived from the average values from the eight thermocouples at the stated flow rate. Both experimental data obtained in the two test modules showed that the trend of the water flow in minichannel is similar with that of the prediction of the simulation results. It can be seen that the average Nusselt number for both minichannel heat sinks increase with Reynolds number because the thermal boundary layer thickness decreases with increased fluid velocity. Nevertheless, the heat transfer performance for the minichannel with cylindrical oblique cut fin is significantly higher than conventional minichannel heat sink. The average Nusselt numbers for both configurations are almost equivalent at the lower Reynolds number of 50 since the flow is considered zero and convection heat transfer is negligible. However, the average Nusselt number increase to as much as 75.64%, from 8.58 to 15.07 when the Reynolds number reaches 460. This noticeable enhancement in heat transfer is due to the combined effects of thermal boundary layer re-development at the leading edge of each cylindrical oblique fin and the secondary flows generated by flow diversion through the oblique fins.

Apart from the total heat transfer enhancement based on the various flow rates, the cylindrical oblique fin heat sink also leads to a greater local heat removal capability across the heat sink surface. FIG. 8B shows an example of the detailed results of the local Nusselt number at different locations for both conventional and cylindrical oblique cut fin based on Eq.(24), when Re is 310. It is observed that cylindrical oblique cut fin heat sink has a consistently higher Nusselt number compared to conventional heat sink at all locations within the heat sink. At the first location which is 13 mm from the flow entrance, the local Nusselt number enhancement is as high as 126% compared with the conventional heat sink. The minimal local Nusselt number enhancement is 57%.

The total thermal resistance comprises of conductive, convective and caloric thermal resistance. The conductive thermal resistance is greatly dependent on the heat sink material property and both use the same copper material with a thermal conductivity of 387.6 W/m·K. Thus the conductive thermal resistance is the same for both heat sinks. The caloric thermal resistance reduces with increasing flow rate however it is not a significant term in liquid cooling system since ρcₚ is very high and have little effect on the thermal resistance. The convective thermal resistance reduces with increasing Reynolds number and results in lower total thermal resistance.

FIG. 8C shows the graph of the experimental and numerical total thermal resistance against Reynolds number for both conventional heat sink and cylindrical oblique fin heat sink. As shown in FIG. 8C, the experimental and numerical result matches closely and the differences are all within 12% tolerance. As the flow rate increases, the Reynolds number rises and the total thermal resistance in minichannel decreases exponentially. FIG. 8C shows the total thermal resistance of the cylindrical oblique fin minichannel (Rₜₒₜ=0.02895° C./W) reduces by as much as 59.1% compared with the conventional minichannel (Rₜₒₜ=0.04605° C./W) when the Reynolds number is around 460. Since the oblique fins on the cylindrical heat sink surface generate uniform secondary flow and increase the total wet surface area, the average wall temperature of the oblique fin surface is much lower than the straight fin minichannel. This phenomenon reduces the total thermal resistance significantly.

### Pressure Drop Characteristic

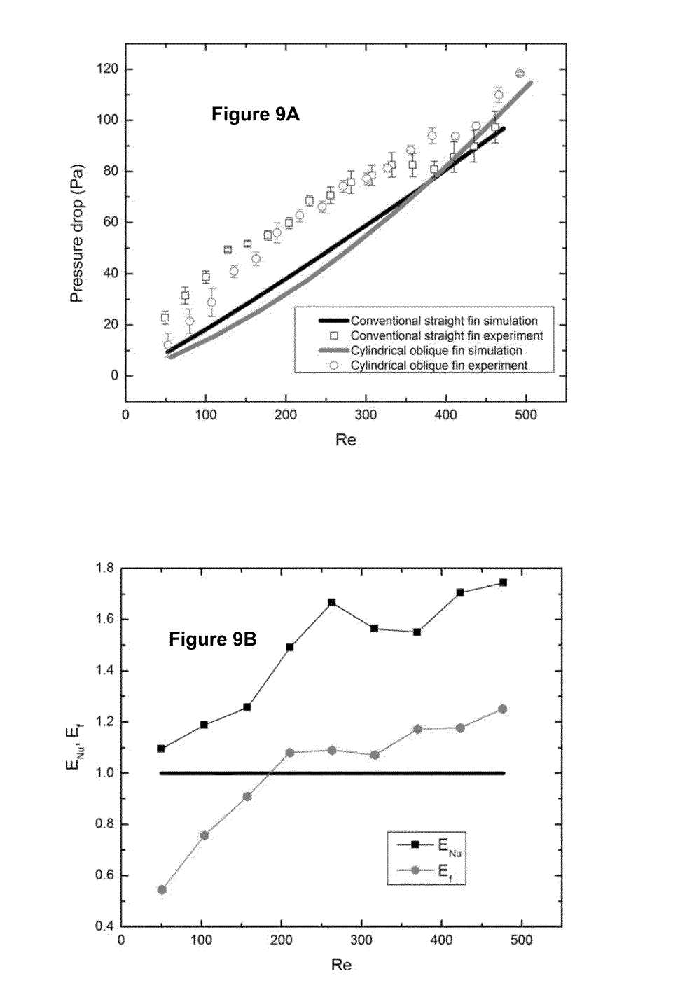

FIG. 9A plots the pressure drop comparison between inlet and outlet of the two heat sinks. The solid line shows the simulation results while all the discrete data represent the experimental data for the thermal developing laminar flow at Reynolds number from 50 to 500 for both conventional and cylindrical oblique fin minichannel heat sinks. The experimental data obtained in the test modules showed that the pressure drop trend in the two minichannels is similar with that of the prediction of the simulation results generally. The pressure drop deviation was higher than expected for the both minichannel heat sinks at lower Reynolds number region. This discrepancy was thought to be due to the uncertainties in channel dimensions, surface roughness and flow rate measurement errors. The pressure drop increases as the Reynolds number increases because as the coolant flow rate increases, the more frictional loss it faces as it transverses through the heat sink. However, a significant heat transfer augmentation of the cylindrical oblique fin minichannel heat sink is achieved with a small pressure drop penalty compared with the conventional minichannel. At low Reynolds number, the pressure drop for conventional heat sink is a little bit higher than the cylindrical oblique fin configuration. This is probably because most of the coolant flow through the main channel with very little flow going though the secondary channels. As the Reynolds number increases, a higher percentage of coolant is diverted into the oblique channels. This creates a stronger secondary flow which further augments the heat transfer but incurs additional pressure drop penalty. Therefore, the pressure drop for oblique fin minichannel starts to deviate and increases more than the conventional configuration when Reynolds number beyond 350. As shown in FIG. 9A the maximum pressure drop of the cylindrical oblique cut fin minichannel is 106 Pa while for conventional minichannel it is 97 Pa when the Reynolds number is around 460. Therefore, the cylindrical oblique cut fin heat sink generates secondary flow which enhances its heat transfer performance yet maintains a comparable pressure drop compared with the conventional heat sink.

FIG. 9B shows the average heat transfer enhancement and pressure drop penalty for different Reynolds number for the conventional straight fin channel and cylindrical oblique fin channel. The heat transfer enhancement (E_{Nu}) and pressure drop penalty (E_{f}) are defined as the average Nusselt number and friction factor of the cylindrical oblique fin channel divided by that of conventional straight fin channel respectively. As shown by the E_{Nu} line, the value is always higher than 1 which implies that the oblique fin channel is superior to conventional straight fin channel in heat transfer performance. For the case of the line E_{f}, at Reynolds number from 50-200, the overall friction factor of the oblique fin minichannel is lower than the conventional straight minichannel however at higher Reynolds number, the friction factor for the conventional minichannel is lower. It should be noted that at higher Reynolds number, the heat transfer performance is much improved about 74% for the oblique fin minichannel over the conventional straight minichannel while friction factor increases only about 20%. This shows that this cylindrical oblique fin minichannel can improve energy efficiency significantly and save more pumping power overall.

1. A heat sink device for use with a component for the heat transfer, the device comprising:
a base having a curvilinear surface;
an inlet for receiving a fluid;
an outlet for venting said fluid;
a heat transfer zone located on said surface and intermediate the inlet and outlet;
said zone including a plurality of transverse channels and a plurality of oblique channels extending between adjacent transverse channels;
wherein said oblique and transverse channels define a fluid path for a fluid from the inlet to the outlet.

2. The heat sink device according to claim 1, wherein the cross-sectional area of any one of the oblique channels is less than the cross-section area of the transverse channels between which the oblique channel extend.

3. The heat sink device according to claim 1, wherein elements of the heat transfer zone separating the channels include heat transfer fins, said fins in heat transfer communication with the component.

4. The heat sink device according to claim 3, wherein said heat transfer fins include an upstream face defining one boundary of said oblique channel said face including a rounded upstream edge.

5. The heat sink device according to claim 3, wherein said heat transfer fins include an upstream face defining one boundary of said oblique channel said face including a rounded downstream edge.

6. The heat sink device according to claim 1, wherein the curvi-linear surface defines a closed shape.

7. The heat sink device according to claim 1, wherein the curvi-linear surface defines an open shape.

8. The heat sink device according to claim 1, wherein said component is a heat sink, said heat transfer device arranged to heat transfer from said fluid to said component.

9. The heat sink device according to claim 1, wherein said heat transfer device is arranged to be mounted to said component.

10. The heat sink device according to claim 1, wherein said heat transfer device is arranged to be formed unitarily with said component.

11. A heat sink device for use with a component for the heat transfer, the device comprising:
a base having a cylindrical surface;
an inlet for receiving a fluid;
an outlet for venting said fluid;
a heat transfer zone located on said surface and intermediate the inlet and outlet;
said zone including a plurality of transverse channels and a plurality of oblique channels extending between adjacent transverse channels;
wherein said oblique and transverse channels define a fluid path for said fluid from the inlet to the outlet.

12. The heat sink device according to claim 11, wherein the cross-sectional area of any one of the oblique channels is less than the cross-section area of the transverse channels between which the oblique channels extend.

13. A process for forming a heat sink device for use with a component for the heat transfer, the process comprising the steps of:
forming a base;
forming a heat transfer zone on said surface;
said zone including a plurality of transverse channels and a plurality of oblique channels extending between adjacent transverse channels;
wherein said oblique and transverse channels define a fluid path for said fluid from the inlet to the outlet.

14. The process according to claim 13, wherein the forming step includes molding the base into a curvilinear surface corresponding to said component.

15. The process according to claim 13, wherein the forming step includes forming the base into a planar shape and then deforming the planar base into a curvilinear surface corresponding to said component.
